(19) United States
(12) Patent Application Publication
(10) Pub. No.: US 2021/0359276 A1
(43) Pub. Date: Nov. 18, 2021

(54) METHOD FOR PRODUCING PARTITION WALL, IMAGE DISPLAY DEVICE AND METHOD FOR PRODUCING SAME

(71) Applicant: KANEKA CORPORATION, Osaka (JP)

(72) Inventors: Hirofumi Inari, Osaka (JP); Hiroshi Yoshimoto, Osaka (JP); Masahito Ide, Osaka (JP); Takao Manabe, Osaka (JP)

(73) Assignee: KANEKA CORPORATION, Osaka (JP)

(21) Appl. No.: 17/193,769

(22) PCT Filed: Sep. 5, 2019
(86) PCT No.: PCT/JP2019/035079

§ 371 Date: Mar. 5, 2021

(30) Foreign Application Priority Data
Sep. 6, 2018 (JP) 2018-166954

(51) Int. Cl. H01L 51/52; H01L 51/56; H01L 27/32

(52) U.S. Cl. CPC H01L 51/5281; H01L 27/322; H01L 51/56

(57) ABSTRACT

The present disclosure is directed to a light-shielding colored resin layer formed on a substrate, and a patterned protective layer formed on the colored resin layer. By removing the colored resin layer exposed in an opening of the protective layer by dry etching, thereby patterning the colored resin layer, a partition wall in which the protective layer is provided on a patterned colored resin layer is formed. This partition wall partitions the display surface of an image display device into a plurality of regions; and an image display device is formed by filling spaces, which are partitioned by the partition wall, with a color developing material.

### TECHNICAL FIELD

One or more embodiments of the present invention relate to a method for producing a partition wall provided at a boundary between pixels of an image display device, and an image display device and a method for producing the image display device.

### BACKGROUND

In an image display device such as a liquid crystal display element or an organic electroluminescent (EL) display element, a black layer (black matrix) patterned with a grid pattern is provided in order to partition the substrate surface into a plurality of regions to form pixels. Furthermore, an organic EL light emitting element has been proposed in which a light-shielding partition wall (bank) is provided at the boundary portion of pixels on an electrode and the inside of the partition wall is filled with a light emitting material or a wavelength conversion material. As shown in Patent Document 1, the partition walls described above can be formed by applying a photosensitive resin composition containing a colorant to a substrate to form a coating film and patterning the coating film by photolithography.

### PATENT DOCUMENT

Patent Document 1: WO 2013/069789 A

### SUMMARY

The higher the partition wall provided at the boundary of the pixels is (the thicker the black layer is), the higher the optical density of the partition wall is, so that the contrast of the image display device tends to improve. Furthermore, the higher the partition wall is, the larger the filling amount (filling thickness) of the light emitting material or the coloring matter can be in the space partitioned by the partition wall, so that the color reproducibility of the image display device can be improved.

In negative photosensitive materials, irradiation with active light such as ultraviolet rays causes generation of a radical, an acid, or the like from a photopolymerization initiator to promote a curing reaction. However, in photosensitive resin compositions containing a colorant, the colorant absorbs a large amount of active light, and therefore, only a small amount of active light reaches the bottom (substrate side) during exposure. As a result, the photocuring is more likely to be insufficient at the bottom than at the light-irradiated surface. The tendency is more remarkable as the thickness of the black layer and the optical density are increased. If the curing is insufficient at the bottom, undercut is promoted at the bottom during development, so that an appropriate pattern cannot be formed. Also in positive photosensitive resin compositions containing a colorant, only a small amount of active light reaches the bottom surface. Therefore, the bottom surface is not removed by development, so that an appropriate pattern cannot be formed.

As described above, in the case of using a photosensitive resin composition containing a colorant, there is a limit to increasing the height of the partition wall. One or more embodiments of present invention relate to providing a method for producing a light-shielding partition wall that provides a good patterning property even when the partition wall is high.

One or more embodiments of the present invention relate to the formation of a light-shielding partition wall that partitions a display surface of an image display device into a plurality of regions. A light-shielding colored resin layer is formed on a substrate, and a patterned protective layer is formed on the colored resin layer. By removing the colored resin layer exposed in an opening of the protective layer by dry etching, the colored resin layer is patterned and a partition wall is formed.

The colored resin layer is typically black, and may have an optical density of 1.5 or more. The colored resin layer may have a thickness (height of the partition wall) of 5 μm or more. The colored resin layer may have an optical density of 2.0 or more, and a thickness of 10 μm or more.

The colored resin layer is formed by, for example, heat-curing of a thermosetting resin composition containing a colorant on the substrate. By using heat-curing, curing can be performed uniformly in the thickness direction even when a colorant is contained.

A coat of a photosensitive resin composition is formed on the colored resin layer, and exposed and developed for patterning to form a protective layer having an opening. The formation thickness of the protective layer (thickness of the coat of the photosensitive resin composition) may be ⅓ or less of the formation thickness of the colored resin layer.

The dry etching can be performed using an oxygen gas, a rare gas, a hydrocarbon gas, and the like. In the dry etching, the protective layer is sometimes etched in addition to the colored resin layer. From the viewpoint of etching the colored resin layer selectively, the etching rate of the colored resin layer may be 10 times or more the etching rate of the protective layer.

In order to reduce the etching rate of the protective layer, it may be preferable to use a silicon element-containing resin such as a polysiloxane compound as the resin material forming the protective layer. The protective layer may contain a silicon atom at a content of 10% by weight or more.

The pixels of the image display device are formed by filling the space surrounded by the partition wall with a color developing material. Examples of the color developing material include light emitting materials, color conversion materials (wavelength conversion materials), and light absorbing materials. The color developing material may be filled by a wet method such as an ink-jet method in the space surrounded by the partition wall.

By the above-described method, a light-shielding partition wall can be formed that has a large height and a high optical density to contribute to improvement in contrast and color reproducibility of an image display device.

### BRIEF DESCRIPTION OF THE DRAWINGS

FIGS. 1A-1F show a conceptual diagram for illustrating a method of forming a partition wall on a substrate.

FIG. 2 is a sectional view of an organic EL display device.

FIG. 3A is a scanning electron microscope (SEM) photograph of a section of a laminate before etching in an example, and FIG. 3B is a SEM photograph of the section of the laminate after etching (partition wall). FIG. 3C is an enlarged SEM photograph of the partition wall.

FIG. 4 is a SEM photograph of a section of a partition wall prepared in a comparative example.

### DETAILED DESCRIPTION OF THE EMBODIMENTS

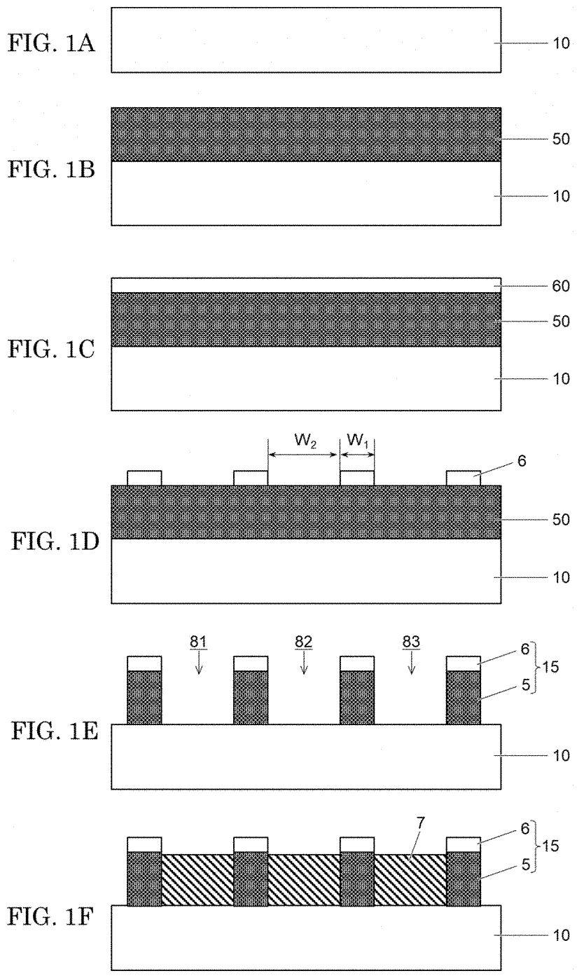

FIG. 1 is a conceptual diagram showing an example of a process of forming a partition wall 15 on a substrate 10. The partition wall 15 is light-shielding, and partitions the display surface of an image display device on the substrate 10 into a plurality of regions. The pixels of the image display device are formed by filling spaces 81, 82, and 83 surrounded by the partition wall 15 with a color developing material 7.

[Formation of Partition Wall]

First, a substrate 10 is prepared (FIG. 1A), and a light-shielding colored resin layer 50 is formed on the substrate 10 (FIG. 1B). A patterned protective layer 6 is formed on the colored resin layer 50 (FIGS. 1C and 1D), and the colored resin layer is patterned by removing the colored resin layer 50 exposed in an opening of the protective layer 6 by dry etching to form a partition wall 15 including a colored resin layer 5 patterned and laminated with the protective layer 6 (FIG. 1E).

<Substrate>

The substrate 10 is not particularly limited as long as it is used as a substrate of an image display device, and glass or a resin material is used. The substrate 10 may be rigid or flexible. The substrate 10 may include a sealing film, an electrode, a thin film transistor (TFT), a light reflection layer, an antireflection layer, and the like.

In an image display device in which light is extracted from the substrate 10 side or an image display device in which light from a backlight is incident from the substrate 10 side, the substrate 10 may be transparent. In an image display device in which light is not incident or emitted from the substrate 10 side, such as a top-emission organic EL display device, the substrate 10 does not need to be transparent.

<Formation of Colored Resin Layer>

The light-shielding colored resin layer 50 containing a binder resin and a colorant is formed on the substrate 10 (FIG. 1B). The method of forming the colored resin layer 50 is not particularly limited. The colored resin layer 50 may be formed by laminating the substrate 10 with a preformed resin layer by a press or the like, or by applying a colored resin composition containing a binder resin and a colorant to the substrate 10.

The colored resin layer 50 serves as a base for the partition wall 15. From the viewpoint of increasing the volumes of the spaces 81, 82, and 83 separated by the partition wall 15 and increasing the optical density of the partition wall, the thickness of the colored resin layer 50 may be 3 μm or more, 5 μm or more, 7 μm or more, 10 μm or more, 12 μm or more, or 15 μm or more. The upper limit of the thickness of the colored resin layer is not particularly limited. From the viewpoint of reducing the thickness of the image display device and shortening the patterning (dry etching) time, the upper limit may be 100 μm or less, or 80 μm or less. The thickness of the colored resin layer may be 50 μm or less, 40 μm or less, 30 μm or less, or 25 μm or less.

From the viewpoint of improving the contrast of the image display device, the optical density of the colored resin layer 50 may be 1.5 or more, and may be 2 or more, 2.5 or more, or 3 or more. The upper limit of the optical density of the colored resin layer 50 is not particularly limited. The upper limit is generally 10 or less, and may be 5 or less. The optical density is based on ISO luminosity.

The binder resin of the colored resin composition may be a thermoplastic resin or a thermosetting resin. Thermosetting resins may be preferable such as acrylic resins, phenol resins, imide resins, and epoxy resins because such resins achieve sufficient hardness in a partition wall having a small width and are unlikely to be eroded by a filling material such as an ink. Even a thermosetting resin containing a colorant can be cured uniformly in the thickness direction.

Examples of the colorant include organic pigments, inorganic pigments, and dyes. From the viewpoint of heat resistance and colorability, pigments may be used as the colorant.

Examples of the organic pigment that absorbs visible light in a wide wavelength range include anthraquinone-based black pigments, perylene-based black pigments, azo-based black pigments, and lactam-based black pigments. Among these pigments, the perylene-based black pigments and the lactam-based black pigments may be preferable from the viewpoint of improving the light-shielding property efficiently. Examples of the inorganic pigment include metal oxides such as composite metal oxide pigments, carbon black, black low-valent titanium oxynitride, titanium oxide, barium sulfate, zinc flower, lead sulfate, yellow lead, red iron oxide, ultramarine blue, Prussian blue, chromium oxide, antimony white, iron black, red lead, zinc sulfide, cadmium yellow, cadmium red, zinc, manganese purple, cobalt purple, barium sulfate, and magnesium carbonate, metal sulfides, sulfates, metal hydroxides, and metal carbonates. Examples of the dye include azo-based, anthraquinone-based, perylene-based, perinone-based, phthalocyanine-based, carbonium-based, and indigoid-based compounds.

The colorants may be used in combination of two or more kinds thereof. For example, a mixed color pigment may be used in which two or more kinds of chromatic pigments are blended so that the resulting mixture is black, that is, the resulting mixture widely absorbs light having a wavelength in the visible light region. In order to reduce the light transmittance efficiently, the mixed color pigment may contain a blue pigment and/or a purple pigment.

The colored resin composition may contain a solvent in addition to the binder resin and the colorant. As the solvent, a solvent capable of dissolving the binder resin and dissolving or dispersing the colorant can be used without particular limitation. The colored resin composition may contain various additives. For example, in the case of a thermosetting binder resin, the resin composition may contain a thermal polymerization initiator, a crosslinking agent, and the like.

The colored resin layer 50 is formed by applying the colored resin composition on the substrate 10 and, if necessary, drying and removing the solvent. As the method of applying, a general coating method can be used such as spin coating, slit coating, or screen coating as long as uniform coating is possible. In the case of a thermosetting binder resin, curing may be performed by heating. The heating temperature for curing can be set within a range where the substrate 10 has heat resistance, and is, for example, about 100 to 300° C.

As will be described below, the colored resin layer 50 is patterned by dry etching Therefore, the colored resin layer may be a material having a high etching property (easily etched) by dry etching If the binder resin included in the colored resin layer contains an Si atom at a large content, the etching property by a gas such as oxygen tends to decrease. Therefore, the content of an Si atom in the colored resin layer 50 may be 5% by weight or less, 3% by weight or less, or 1% by weight or less. The colored resin layer 50 does not need to contain a silicon atom.

<Protective Layer>

The patterned protective layer 6 is formed on the colored resin layer 50 (FIG. 1D). The protective layer 6 functions as a mask during patterning the colored resin layer 50 by dry etching (dry etching resist). The colored resin layer 50 is not etched in the region where the protective layer 6 is provided, and the colored resin layer is etched in the opening where no protective layer is provided. Therefore, the width W₁ of the protective layer 6 is substantially equal to the width of the partition wall 15, and the width W₂ of the opening corresponds to the width of the pixel of the image display device. W₁ is about 5 to 100 μm, and W₂ is about 10 to 500 μm.

The method of forming the patterned protective layer 6 is not particularly limited, and a may be method in which a coat 60 of a photosensitive resin composition is formed on the colored resin layer 50 and then patterned by photolithography as shown in FIG. 1C because a fine pattern can be formed.

The photosensitive resin composition is not particularly limited as long as it contains a binder resin and a photosensitizer and can be patterned by photolithography, and may be a positive or negative photosensitive resin composition. As the photosensitive resin composition, an appropriate dry etching resist material can be used.

Examples of the binder resin of the photosensitive resin composition include acrylic resins, phenol resins, polysiloxane resins, imide resins, epoxy resins, and alicyclic hydrocarbon resins.

The photosensitizer is a component that induces a desired photoreaction by irradiation with light. The negative photosensitive resin composition contains a photopolymerization initiator such as a photoradical generator, a photoacid generator, or a photobase generator as the photosensitizer, and the binder resin in the exposed portion is cured to be insoluble in alkali. Therefore, when alkali development is performed, the unexposed portion dissolves in the alkaline developer, and the exposed portion remains without being dissolved. The positive photosensitive resin composition contains a naphthoquinone diazide compound and/or a photoacid generator as the photosensitizer, and the photosensitizer imparts alkali solubility to the binder resin by exposure. Therefore, when alkali development is performed, the exposed portion dissolves in the alkaline developer, and the unexposed portion remains without being dissolved.

The photosensitive resin composition may be heat-cured by heating after exposure and development (post-baking) The photosensitive resin composition may contain a solvent in addition to the binder resin and the photosensitizer. As the solvent, a solvent capable of dissolving the binder resin and the photosensitizer can be used without particular limitation. The colored resin composition may contain an additive such as a sensitizer.

The thickness of the protective layer 6 needs to be set so that the protective layer 6 remains when the colored resin layer 50 is etched by dry etching In the case that the etching rate of the protective layer 6 in dry etching is low (the protective layer is difficult to etch), the protective layer 6 functions as a dry etching resist even if the thickness of the protective layer 6 is small. The thickness of the protective layer 6 is, for example, about 0.2 to 10 μm, may be 0.3 μm or more or 0.5 μm or more, and may be 5 μm or less or 3 μm or less. In the case of forming the protective layer 6 by patterning the coat 60 by photolithography, the thickness of the coat 60 is substantially equal to the thickness of the protective layer 6.

The formation thickness of the protective layer 6 may be as small as possible from the viewpoints of improving patterning accuracy and reducing material cost. The formation thickness of the protective layer 6 may be ⅓ or less, ¼ or less, or ⅕ or less of the formation thickness of the colored resin layer 50. The term “formation thickness” refers to the thickness of the layer before patterning by dry etching.

In order for the protective layer 6 having a small thickness to function as a dry etching resist, the etching rate of the protective layer 6 by dry etching may be low. That is, the protective layer 6 may have high dry etching resistance. The dry etching resistance of the protective layer 6 tends to be improved by using a resin, such as a polysiloxane resin, containing an Si atom at a large content, and the resistance to dry etching by oxygen is particularly high. The content of an Si atom in the protective layer may be 10% by weight or more, or 12% by weight or more. The content of an Si atom in the protective layer may be 14% by weight or more, 15% by weight or more, or 16% by weight or more. The content of an Si atom can be quantified by X-ray electron spectroscopy (XPS).

Examples of the photosensitive resin composition containing Si at a large content include compositions containing, as the binder resin, a polymer produced by introducing an alkali-soluble functional group or a polymerizable functional group into a polysiloxane compound by a hydrosilylation reaction. Examples of the negative photosensitive resin composition containing a polysiloxane compound are disclosed in WO 2009/075233 A, WO 2010/038767 A, and the like. Examples of the positive photosensitive resin composition containing a polysiloxane compound are disclosed in WO 2014/007231 A and the like. In particular, from the viewpoint of heat resistance, the binder resin may be a polymer having a cyclic polysiloxane structure.

The protective layer 6 may be transparent or light-shielding. In the case of patterning the coat 60 by photolithography using the photosensitive resin composition, the photosensitive resin composition may contain no colorant from the viewpoint of improving patterning accuracy. Meanwhile, the coat 60 can be patterned by photolithography even if the photosensitive resin composition contains a colorant because the thickness of the coat 60 (protective layer 6) is sufficiently smaller than the thickness of the colored resin layer 50.

As the method of applying the photosensitive resin composition to the colored resin layer 50, a general coating method can be used such as spin coating, slit coating, or screen coating as long as uniform coating is possible.

Before exposure, heating (pre-baking) may be performed to dry the solvent. The heating temperature can be set as appropriate, and may be 50 to 200° C., or 60 to 150° C. Furthermore, vacuum devolatilization may be performed before exposure. The vacuum devolatilization may be performed simultaneously with the heating.

The light source for exposure can be selected according to the sensitivity wavelength of the photosensitizer contained in the photosensitive resin composition. Usually, a light source having a wavelength in the range of 200 to 450 nm (such as a high-pressure mercury lamp, an ultra-high pressure mercury lamp, a metal halide lamp, a high-power metal halide lamp, a xenon lamp, a carbon arc lamp, or a light emitting diode) is used.

The amount of exposure is not particularly limited. The amount is generally 1 to 1,000 mJ/cm², and may be 10 to 500 mJ/cm². If the amount of exposure is excessively small, curing is sometimes insufficient to decrease the pattern contrast, and if the amount of exposure is excessively large, the tact time is sometimes increased to increase the production cost. For the purpose of accelerating the reaction, heating (post-exposure baking) may be performed after exposure and before development.

The coat 60 after exposure is brought into contact with a developer by an immersion method, a spray method, or the like for development. In the negative photosensitive resin composition, the coat in the unexposed portion is dissolved and removed. In the positive photosensitive resin composition, the coat in the exposed portion is dissolved and removed. The developer can be appropriately selected according to the kind of the composition, and an alkaline developer is generally used. Specific examples of the alkaline developer include organic alkaline aqueous solutions such as a tetramethylammonium hydroxide (TMAH) aqueous solution and a choline aqueous solution and inorganic alkaline aqueous solutions such as a potassium hydroxide aqueous solution, a sodium hydroxide aqueous solution, a potassium carbonate aqueous solution, a sodium carbonate aqueous solution, and a lithium carbonate aqueous solution. The alkali concentration of the developer may be 0.01 to 25% by weight, 0.05 to 10% by weight, or 0.1 to 5% by weight. The developer may contain a surfactant or the like for the purpose of adjusting the dissolution rate or the like.

Post-baking may be performed after development to cure the composition of the remaining coat (protective layer 6). The post-baking condition can be set as appropriate. The post-baking temperature may be 100 to 400° C., or 120 to 350° C.

<Dry Etching>

The laminate is dry-etched in which the patterned protective layer 6 is provided on the colored resin layer 50. Since the protective layer 6 functions as a dry etching resist, the colored resin layer 50 is not etched in the region where the protective layer 6 is provided, and the colored resin layer is removed by etching in the opening where no protective layer is provided. As a result, the partition wall 15 that is a laminate of the colored resin layer 5 and the protective layer 6 is formed on the substrate 10 (FIG. 1E).

Dry etching is a method of etching a material with a reactive gas, ion, or radical, and examples of the method include reactive gas etching, reactive ion etching (RIE), and reactive ion beam etching (ion milling) RIE may be particularly preferable because of high processability of resin materials by RIE. The dry etching may be isotropic or anisotropic. Anisotropic etching may be preferable from the viewpoint of suppressing undercut.

Examples of the etching gas used for the dry etching include oxygen atom-containing gases such as an oxygen gas, carbon monoxide, and carbon dioxide; hydrocarbon gases; a hydrogen gas; an ammonia gas; chlorine-based gases such as chlorine and boron chloride; fluorine-based gases; and rare gases such as argon and helium. Among the gases, an oxygen gas, hydrocarbon gases, and rare gases may be used as the etching gas because the etching selectivity of the colored resin layer 50 can be enhanced and the etching of the protective layer 6 can be suppressed.

In the dry etching, not only the colored resin layer 50 but also the protective layer 6 is sometimes etched. In order to etch the colored resin layer 50 wholly in the thickness direction without increasing the thickness of the protective layer 6, the ratio of the etching rate of the colored resin layer 50 to the etching rate of the protective layer 6 by dry etching (selectivity ratio) may be high. The etching rate of the colored resin layer may be 10 times or more, 30 times or more, and may be 50 times or more the etching rate of the protective layer. The etching rate ratio (selectivity ratio) may be 70 times or more, 100 times or more, 150 times or more, or 200 times or more. The etching rate is the amount of change in the film thickness per unit time, and can be calculated from the amount of change in the film thickness in dry etching performed for a predetermined time.

The etching rate ratio can be adjusted by the combination of the materials of the colored resin layer 50 and the protective layer 6, the dry etching condition, and the like. As described above, if a resin material having a large content of an Si atom such as polysiloxane is used as the protective layer 6 (dry etching resist), the etching rate of the protective layer 6 is low, so that the etching rate ratio tends to be high. The higher the etching rate ratio is, the more preferable the etching rate ratio is, and the upper limit is not particularly limited. In the case that the etching rate of the protective layer 6 is 0, that is, the protective layer 6 is not etched by dry etching, the etching rate ratio (selectivity ratio) is infinite.

In the dry etching, it may be preferable that the undercut of the colored resin layer 5 (etching of the colored resin layer located under the protective layer 6) be small. For example, the difference in width between the portion having the largest width and the portion having the smallest width (undercut amount) of the colored resin layer 50 may be 10 μm or less, 7 μm or less, or 5 μm or less. The undercut amount may be ½ or less, or ⅓ or less of the thickness of the colored resin layer 5. As described above, the undercut can be suppressed by applying anisotropic dry etching.

By patterning the colored resin layer by dry etching, the partition wall 15 and a plurality of spaces separated by the partition wall are formed on the substrate surface. FIG. 1E schematically shows a form having four partition walls 15 and three spaces 81, 82, and 83 on the substrate 10. In an actual image display device, the partition wall 15 is formed, for example, in a grid pattern in a planar view on the substrate 10, and spaces (pixels) separated by the partition wall are two-dimensionally arranged. The arrangement pattern of the pixels is not limited to a grid pattern (matrix pattern), and the pixels may be arranged in a houndstooth pattern, a honeycomb pattern, or the like.

The partition wall 15 on the substrate 10 is a laminate of the colored resin layer 5 that is patterned and the protective layer 6 as a dry etching resist. The colored resin layer 5 is, for example, a thermosetting resin layer containing a colorant (a cured product of a thermosetting resin composition). The protective layer 6 may be a transparent resin layer. In the case of forming the protective layer 6 by patterning the coat 60 by photolithography, the protective layer 6 is a cured product of a photosensitive resin composition. In the case of a negative photosensitive resin composition, the protective layer 6 is a photocured product of the resin composition, and may be further heat-cured by post-baking In the case of a positive photosensitive resin composition, the protective layer 6 may be a heat-cured product of the resin composition. The protective layer 6 may be removed after patterning the colored resin layer by dry etching The protective layer 6 may be left as it is after dry etching to be a part of the partition wall.

[Filling of Color Conversion Material (Formation of Pixels)]

The pixels of the image display device are formed by filling the color developing material 7 in the spaces 81, 82, and 83 surrounded by the partition wall 15 formed by removing the colored resin layer 50 by etching The color developing material is, for example, a light emitting material. In an organic EL display device, adjacent spaces 81, 82, and 83 are filled with light emitting materials that emit different colors (have different emission wavelengths) to make color display possible. For example, the space 81, 82, and 83 are filled with a red light emitting material, a green light emitting material, and a blue light emitting material respectively to make color display possible.

The light emitting material is not limited to an organic EL material, and may be an inorganic light emitting diode, a quantum dot material, or the like as long as it can convert external energy such as an electric current or an electromagnetic wave into light energy to emit light. A plurality of materials may be stacked into a laminate in the spaces 81, 82, and 83 to form a light emitting element in the spaces. For example, the organic EL light emitting element may include a functional layer in which a hole injection material, a hole transport material, a hole blocking material, an electron blocking material, an electron transport material, an electron injection material, and the like are formed into a laminate over and under a light emitting layer including an organic EL light emitting material.

The color developing material may be a light absorbing material that absorbs light having a specific wavelength. The light absorbing material forming the pixel of the image display device realizes color display by absorbing light having a specific wavelength and transmitting light having another wavelength. The light absorbing material is typically a colorant (coloring matter) such as a dye or a pigment. For example, a coloring matter that transmits red light, a coloring matter that transmits green light, and a coloring matter that transmits blue light are filled in the spaces 81, 82, and 83 respectively to make color display possible.

The color developing material may be a wavelength conversion material. The wavelength conversion material has a function of converting the wavelength of the emitted light by converting the wavelength of the incident light. For example, the spaces 81, 82, and 83 are filled with different wavelength conversion materials and the wavelength conversion materials are irradiated with light from a light emitting diode, an organic EL light source, or the like to make color display possible.

The method of filling the space surrounded by the partition wall 15 with the color developing material is not particularly limited, and a method depending on the material or the composition of the element can be applied. Examples of the method include wet methods such as coating and ink-jet, dry methods such as vacuum deposition, chemical vapor deposition (CVD), and sputtering, and a mass transfer method. As described above, by the method of patterning the colored resin layer by dry etching, a partition wall that is high (having a large height) can be formed. Therefore, even in the case that the space surrounded by the partition wall is filled with the color developing material by the wet method, a sufficient thickness can be secured. For example, in the case that the color developing material is filled by an ink-jet method, the amount of ink added dropwise to each space (pixel) is easily increased to improve the emission intensity and enhance the color conversion function, and as a result, the contrast and the color reproducibility of the image display device can be improved. Furthermore, since the height of the partition wall is high, color leakage (color mixing) between the pixels can be suppressed.

In the case that the color developing material is filled by a wet method such as an ink-jet method, the protective layer 6 provided on the colored resin layer 5 may have a function as an ink-repellent layer. For example, in the case of the protective layer 6 including a material having a large Si content such as a polysiloxane material, the protective layer 6 has low ink wettability and easily repels ink. Therefore, even when the ink is filled up to the upper surface of the partition wall 15 (the upper surface of the protective layer 6) or when the ink is filled so as to overflow from the upper surface, the adjacent space (pixel) is rarely contaminated with the ink, so that color mixing between the adjacent pixels can be prevented.

[Image Display Device]

As described above, the pixels of the image display device are formed by filling the spaces 81, 82, and 83 surrounded by the partition wall 15 on the substrate 10 with the color conversion material. Examples of the image display device include liquid crystal display devices, organic EL display devices, and micro light emitting diode (LED) display devices in which inorganic LEDs are arranged in a plane. In the liquid crystal display device, a color filter in which the partition wall 15 is a black matrix and the light absorbing material is a color display unit can be formed by using the light absorbing material (coloring matter) as the color developing material. Also in self-luminous display devices such as the organic EL display device and the micro LED display device, colorization of the image can be realized by using a color filter having the above-described configuration.

In the organic EL display device, colorization can be realized by using the light emitting material as the color developing material. Furthermore, in all kinds of image display devices, colorization can be realized by using the color conversion material as the color developing material.

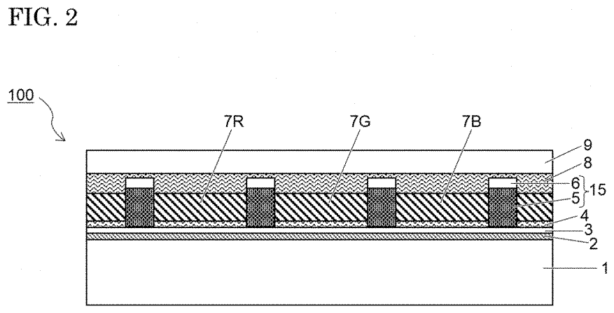

As an example of the image display device, a configuration example of the organic EL display device will be described. FIG. 2 is a sectional view of a top-emission organic EL display device 100 in which a thin film transistor (TFT) 2 that is a driving element is arranged on a substrate 1 so as to correspond to each pixel, and a sealing film 3 covering the TFT is provided. The sealing film 3 has a role of flattening the unevenness of the TFT, and is provided with a through hole for transmitting a signal from the TFT 2 to the electrode of each pixel.

As the substrate 1 of the organic EL display device, a material such as glass or a resin film is used. In the top-emission organic EL display device, the substrate 1 does not need to be transparent, and a colored film such as a polyimide film may be used. In a flexible display or a foldable display, a film substrate may be used such as a polyimide film, a polyethylene terephthalate (PET) film, or a polyethylene naphthalate (PEN) film.

Since the sealing film 3 needs to be provided with a through hole, the sealing film may be formed using a photosensitive resin composition. The sealing film 3 is formed using a photosensitive resin composition on the substrate 1 on which the TFT 2 is formed, and a through hole is formed by photolithography.

Examples of the material of an electrode 4 (positive electrode) include metals and alloys such as aluminum, molybdenum, copper, chromium, titanium, MoCr alloys, NiCr alloys, APC alloys (alloys of silver, palladium, and copper), and ARA alloys (alloys of silver, rubidium, and gold). The electrode material is formed into a film by a vapor deposition method or a sputtering method, then a resist is applied to the film, the resist is patterned by photolithography, the film exposed in an opening of the resist is etched, and then the resist is peeled off to form an electrode 4 having a predetermined pattern.

On the sealing film 3, a partition wall 15 is formed. As described above, the partition wall 15 in which a colored resin layer 5 and a protective layer 6 are stacked into a laminate is formed by dry etching of a colored resin layer 50 using the patterned protective layer 6 as a dry etching mask.

In the segments separated by the partition wall, a red light emitting layer 7R, a green light emitting layer 7G, and a blue light emitting layer 7B are formed. The red light emitting layer 7R contains a red light emitting material, the green light emitting layer 7G contains a green light emitting material, and the blue light emitting layer 7B contains a blue light emitting material. The light emitting material may be a low molecular weight organic light emitting material or a high molecular weight organic light emitting material. The high molecular weight organic light emitting material may be preferable because of its excellent filling property by an ink-jet method. Examples of the high molecular weight organic light emitting material include polyphenylene vinylene and its derivatives, polyacetylene and its derivatives, polyphenylene and its derivatives, polyparaphenylene ethylene and its derivatives, poly3-hexylthiophene (P3HT) and its derivatives, and polyfluorene and its derivatives.

In the light emitting layers 7R, 7G, and 7B, a layer other than the light emitting material layer may be formed such as a hole injection layer, a hole transport layer, a hole blocking layer, an electron blocking layer, an electron transport layer, an electron injection layer, and an intermediate layer (buffer layer). The light emitting layer may include a functional layer in which a material or the like is formed into a layer.

On the light emitting layers 7R, 7G, and 7B, an electrode 8 (negative electrode) is formed, and a sealing layer 9 covering the organic EL element is formed on the electrode 8. As the constituent material of the electrode 8, a conductive oxide may be used such as indium tin oxide (ITO) or indium zinc oxide (IZO) because the electrode 8 provided on the light extraction side needs to have a light transmitting property. The electrode 8 may be a light-transmitting metal thin film The sealing layer 9 has a function of protecting the organic EL element from an external environment such as moisture, and may be an inorganic film or an organic film The sealing layer 9 may be a multilayer film in which an organic film and an inorganic film are stacked. The multilayer film may be used as the sealing layer 9 because the multilayer film has a high effect of suppressing the infiltration of moisture and oxygen.

### EXAMPLES

Hereinafter, one or more embodiments of the present invention will be described in more detail with reference to an example and a comparative example relating to the formation of a black partition wall, but one or more embodiments of the present invention is not limited to the following examples.

[Preparation of Black Colorant]

To 36 g of propylene glycol monomethyl acetate (PGMEA), 10 g of lactam black (“Irgaphor Black S 0100 CF” manufactured by BASF SE) and 4 g of a polymer dispersant (“AJISPER PN411” manufactured by Ajinomoto Fine-Techno Co., Inc.) were added as pigments, and the resulting mixture was stirred with a homogenizer for 3 hours to obtain a colorant A.

[Preparation of Polysiloxane Compound for Protective Layer]

Into a 500 mL four-necked flask, 144.8 g of toluene and 72.4 g of 1,3,5,7-tetrahydrogen-1,3,5,7-tetramethylcyclotetrasiloxane were put, the gas phase was replaced with nitrogen, then a mixed solution of 13.1 g of monomethyl diallyl isocyanurate, 20.7 g of diallyl isocyanurate, 140 g of dioxane, and 0.0306 g of a xylene solution of a platinum-vinylsiloxane complex (containing platinum at a content of 3% by weight) was added dropwise at an internal temperature of 105° C. Disappearance of the allyl group was confirmed by ¹H-NMR, and the reaction was terminated by cooling. Unreacted 1,3,5,7-tetrahydrogen-1,3,5,7-tetramethylcyclotetrasiloxane was distilled under reduced pressure, 200 g of toluene was further added, the gas phase was replaced with nitrogen, and then a mixed solution of 42.3 g of toluene and 42.3 g of vinylcyclohexene oxide was added dropwise at an internal temperature of 105° C. Disappearance of the vinyl group was confirmed by ¹H-NMR, the reaction was terminated by cooling, and then toluene was distilled under reduced pressure to obtain a polysiloxane compound A.

### Example

### Patterning of Black Resin Layer by Dry Etching

<Preparation of Thermosetting Black Resin Composition>

A mixed solution was produced by mixing 100 parts by weight of an acrylic resin solution having an acidic functional group (“PHORET ZAH-110” manufactured by Soken Chemical & Engineering Co., Ltd., non-volatile content: 35% by weight), 10 parts by weight of a bifunctional epoxy compound (3′,4′-epoxycyclohexylmethyl-3,4-epoxycyclohexanecarboxylate: “CELLOXIDE 2021P” manufactured by Daicel Corporation), 2 parts by weight of the colorant A, 1 part by weight of diphenyliodonium hexafluorophosphate as a thermal polymerization initiator (thermal acid generator), and 5 parts by weight of PGMEA as a solvent, and the mixed solution was filtered through a membrane filter having a mesh-opening of 0.2 μm to prepare a thermosetting black resin composition.

<Formation of Black Resin Layer>

To a non-alkali glass substrate having a size of 100 mm×100 mm, the resin composition was applied by spin coating, the resulting product was pre-baked (the solvent was dried) by heating on a hot plate at 100° C. for 2 minutes, and then post-baked (heat-cured) by heating in an oven at 230° C. for 30 minutes to form a black resin layer A having a thickness of 18.6 μm. The black resin layer A had an optical density of 3.1. The optical density was measured with a transmission densitometer (“X-Rite 361T” manufactured by X-Rite).

<Preparation of Photosensitive Resin Composition for Formation of Protective Layer>

A mixed solution was produced by mixing 100 parts by weight of the polysiloxane compound A, 3 parts by weight of triphenylsulfonium hexafluorophosphate as a photoacid generator, 2 parts by weight of 9,10-dibutoxyanthracene as a sensitizer, and 200 parts by weight of PGMEA as a solvent, and the mixed solution was filtered through a membrane filter having a mesh-opening of 0.2 μm to prepare a negative photosensitive resin composition.

<Formation of Protective Layer>

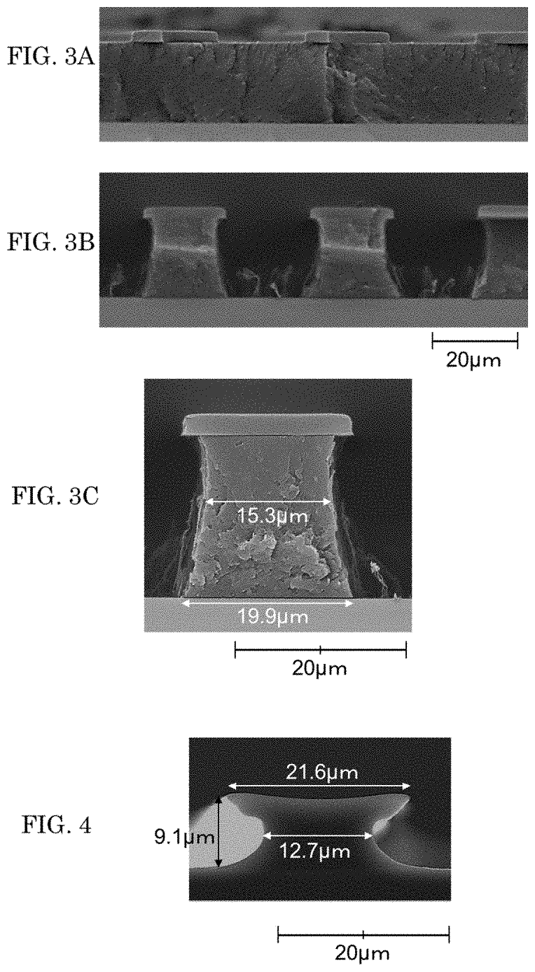

The photosensitive resin composition was applied to the black resin layer A by spin coating, and the resulting product was exposed through a photomask having a 20 μm line-and-space pattern using a mask aligner (“MA-1300” manufactured by Japan Science Engineering Co., Ltd.) in an integrated light amount of 50 mJ/cm², and then immersed in an alkaline developer (2.38% TMAH aqueous solution manufactured by TAMA CHEMICALS CO., LTD.) at 23° C. for 70 seconds for development. Furthermore, the resulting product was post-baked in an oven at 230° C. for 30 minutes to form a protective layer having a film thickness of 2.7 μm (see FIG. 3A). The protective layer was subjected to elemental analysis by X-ray electron spectroscopy (XPS) and confirmed to have a proportion of an Si atom of 18% by weight.

<Dry Etching of Black Resin Layer>

A sample including the black resin layer and the patterned protective layer on the glass substrate was dry-etched under the following conditions using an inductively coupled plasma reactive ion etching apparatus (“RIE800” manufactured by Samco Inc.).

Gas: oxygen

Gas flow rate: 10 sccm

Applied power: 200 W

At an etching time of 5, 30, and 70 minutes, the residual film thickness of the protective layer and the residual film thickness of the black resin layer in the region where no protective layer was formed were determined from the SEM photograph of the section of the sample. From the plot of the time and the residual film thickness, the etching rate was calculated. Table 1 shows the residual film thickness at each etching time and the etching rates of the black resin layer and the protective layer. FIG. 3A is a SEM photograph of the section of the laminate before etching, and FIG. 3B is a SEM photograph of the section of the laminate after 70 minutes of dry etching (partition wall). FIG. 3C is an enlarged SEM photograph of the section of the partition wall.

TABLE 1

| | Etching time (min) | | | | Etching rate |
|---|---|---|---|---|---|
| | 0 | 5 | 30 | 70 | (nm/min) |
| Black resin layer (nm) | 18600 | 17260 | 10550 | 0 | 265.7 |
| Protective layer (nm) | 2730 | 2720 | 2710 | 2680 | 0.67 |

As shown in Table 1, the etching rate of the black resin layer was about 400 times the etching rate of the protective layer, showing a sufficient etching selectivity ratio. As shown in FIG. 3C, the difference between the maximum width and the minimum width of the partition wall after the patterning was 4.6 μm, and formation of a good pattern shape was confirmed.

### Comparative Example

### Patterning of Black Film by Photolithography

<Preparation of Photosensitive Black Resin Composition>

A mixed solution was produced by mixing 100 parts by weight of an acrylic resin solution having an acidic functional group (“PHORET ZAH-110” manufactured by Soken Chemical & Engineering Co., Ltd.), 20 parts by weight of a bifunctional epoxy compound (“CELLOXIDE 2021P” manufactured by Daicel Corporation), 3 parts by weight of the colorant A, 5 parts by weight of triphenylsulfonium hexafluorophosphate as a photopolymerization initiator (photoacid generator), 2 parts by weight of 9,10-dibutoxyanthracene as a sensitizer, and 5 parts by weight of PGMEA as a solvent, and the mixed solution was filtered through a membrane filter having a mesh-opening of 0.2 μm to prepare a photosensitive black resin composition B.

<Formation of Black Resin Layer>

To a non-alkali glass substrate having a size of 100 mm×100 mm, the resin composition B was applied by spin coating, and the resulting product was pre-baked by heating on a hot plate at 100° C. for 2 minutes. By adjusting the spin coating rotation speed, two kinds of samples having a film thickness of 10.6 μm and 18.5 μm were prepared. The black resin layer B having a film thickness of 10.6 μm had an optical density of 1.8, and the black resin layer B having a film thickness of 18.5 μm had an optical density of 3.3.

The resulting product was exposed through a photomask having a 20 μm line-and-space pattern using a mask aligner (integrated light amount: 500 mJ/cm², 800 mJ/cm², or 1,000 mJ/cm²) and then immersed in an alkaline developer (2.38% TMAH aqueous solution) at 23° C. for 180 seconds for development. Furthermore, the resulting product was post-baked in an oven at 230° C. for 30 minutes to form a patterned black resin layer.

In the case of the black resin layer B having a thickness of 18.5 μm, the pattern was peeled off from the substrate during the development in each exposure amount, and no partition wall (pattern film) was formed. The black resin layer having a thickness of 10.6 μm exposed in an exposure amount of 1,000 mJ/cm² was patterned, but in the case of the samples exposed in an exposure amount of 500 mJ/cm² and 800 mJ/cm², the pattern was peeled off from the substrate during the development.

FIG. 4 is a SEM photograph of the section of the partition wall formed by exposing the black resin layer B having a thickness of 10.6 μm in an exposure amount of 1,000 mJ/cm² and developing the exposed black resin layer B. In FIG. 4, the difference between the maximum width and the minimum width of the partition wall is 8.9 μm, and it can be seen that the undercut is larger even though the height of the partition wall is smaller than in the above-described example (FIG. 3C). This is because the photocuring of the photosensitive resin sufficiently proceeded at the light-irradiated surface (upper surface of the partition wall) to secure a sufficient width, but the closer to the bottom the photosensitive resin was, the less sufficiently the photosensitive resin was photocured, and the more the photosensitive resin was dissolved in the alkali.

From the above-described results, it is found that the height of the partition wall is difficult to increase in the photolithography of the black photosensitive resin composition, and that formation of a pattern needs a large exposure amount even if the height of the partition wall is small, so that the productivity is deteriorated. Meanwhile, it is found that by patterning the black resin layer by dry etching, a partition wall can be formed that has a large height and enables formation of a good pattern shape.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### DESCRIPTION OF REFERENCE SIGNS

10 substrate
15 partition wall
5,60 colored resin layer
6,60 protective layer (dry etching resist)
1 substrate
2 TFT
3 sealing film
4,8 electrode
7R, 7G, 7B organic EL light emitting layer
9 sealing layer
100 organic EL display device

1. A method for producing a light-shielding partition wall that partitions a display surface of an image display device into a plurality of regions, the method comprising:
forming a colored resin layer that is light-shielding on a substrate;
forming a protective layer patterned by forming a coat of a photosensitive resin composition that contains a polysiloxane compound on the colored resin layer and exposing and developing the coat; and
patterning the colored resin layer by removing the colored resin layer exposed in an opening of the protective layer by dry etching

2. The method according to claim 1, wherein the colored resin layer has a thickness of 5 μm or more.

3. The method according to claim 1, wherein the colored resin layer has an optical density of 1.5 or more.

4. The method according to claim 1, wherein the colored resin layer is formed by thermosetting a thermosetting resin composition containing a colorant on the substrate.

5. The method according to claim 1, wherein a formation thickness of the protective layer is ⅓ or less of a formation thickness of the colored resin layer.

6. The method according to claim 1, wherein the protective layer has a thickness of 0.2 to 10 μm.

7. The method according to claim 1, wherein the protective layer contains a silicon atom at a content of 10% by weight or more.

8. The method according to claim 1, wherein the dry etching is performed using at least one gas selected from the group consisting of an oxygen gas, rare gases, and hydrocarbon gases.

9. The method according to claim 1, wherein in the dry etching, an etching rate of the colored resin layer is 10 times or more an etching rate of the protective layer.

10. A method for producing an image display device, the method comprising:
forming a partition wall on a substrate by the method according to claim 1; and
filling a space surrounded by the partition wall with at least one color developing material selected from the group consisting of light emitting materials, wavelength conversion materials, and light absorbing materials.

11. The method according to claim 10, wherein the at least one color developing material is filled by a wet method.

12. The method according to claim 11, wherein the at least one color developing material is filled by an ink-jet method.

13. An image display device comprising:
a partition wall that is light-shielding,
the partition wall including a light-shielding colored resin layer and a transparent resin layer on the light-shielding colored resin layer,
the light-shielding colored resin layer including a cured product of a thermosetting resin composition containing a colorant,
the transparent resin layer including a cured product of a photosensitive resin composition that contains a polysiloxane compound;
a display surface partitioned into a plurality of regions with the partition wall; and
at least one color developing material selected from the group consisting of light emitting materials, wavelength conversion materials, and light absorbing materials, wherein the at least one color developing material is filled in a space surrounded by the partition wall.
